(19) United States
(12) Patent Application Publication
(10) Pub. No.: US 2014/0184272 A1
(43) Pub. Date: Jul. 3, 2014

(54) METHOD OF SIGNAL IDENTIFICATION BY USING RING OSCILLATOR BASED CLOCK AND RELATED APPARATUS THEREOF

(71) Applicant: JMICRON TECHNOLOGY CORP., Hsin-Chu (TW)

(72) Inventors: Li-Kuo Liu, Hsinchu City (TW); Kuo-Kuang Chen, New Taipei City (TW)

(73) Assignee: JMicron Technology Corp., Hsin-Chu (TW)

(21) Appl. No.: 13/761,143

(22) Filed: Feb. 6, 2013

(30) Foreign Application Priority Data
Dec. 28, 2012 (TW) 101151006

(51) Int. Cl. G01R 23/15

(52) U.S. Cl. CPC G01R 23/15
USPC 327/42

(57) ABSTRACT

A method of signal identification, including: receiving a signal; utilizing a clock generated by a ring oscillator to sample the signal continuously to generate a plurality of sampled signals; counting each sampled signal length corresponding to successive sampled signals each having an identical value; and identifying a content of the signal according to a plurality of sampled signal lengths. A signal identification apparatus, including: a receiving circuit, arranged for receiving a signal; a ring oscillator, arranged for generating a clock; a sampling circuit, arranged for sampling the signal continuously to generate a plurality of sampled signal; a counter, arranged for counting each sampled signal length corresponding to successive sampled signals each having an identical value; and a determining unit, arranged for identifying a content of the signal according to a plurality of sampled signal lengths.

### BACKGROUND OF THE INVENTION

1. Field of the Invention

The disclosed embodiments of the present invention relate to signal identification, and more particularly, to a method of utilizing a ring oscillator to replace a phase-lock loop (PLL) to generate a clock, and sampling and identifying a signal according to the clock, and a related circuit thereof.

2. Description of the Prior Art

The solid-state drive (SSD) in recent years gradually consolidates its position in the storage media market, and is widely used in personal computers and a variety of mobile devices. The serial advanced technology attachment (SATA) interface becomes the current SSD interface mainstream. Due to the increasingly urgent demand for reducing power consumption of various types of devices, the SATA specification defines a slumber mode for the SATA device, which is particularly important for applications with long periods of idle time.

While a SATA device is in the slumber mode, a SATA host must send the specific Out-of-band (OOB) signals as shown in sub-diagrams (a) and (b) of FIG. 1 to wake up the SATA device, wherein the sub-diagram (a) of FIG. 1 illustrates the waveform of the COMRESET/COMINIT signal, and the sub-diagram (b) of FIG. 1 illustrates the waveform of the COMWAKE signal. Traditionally, in the slumber mode, at least a receiving circuit and a phase-locked loop of a front-end circuit of a SATA device must be retained to ensure that the OOB signals transmitted from a SATA host can be identified by the SATA device. Therefore, the power consumption of the PLL has become the main factor of the power consumption in the slumber mode; however, the design of the PLL is matured, and reducing the power consumption via a PLL redesign is difficult. Thus, there is a need for an innovative design which significantly reduces the power consumption of a device in the slumber, and is also able to identify the OOB signals to exit the slumber mode.

### SUMMARY OF THE INVENTION

Therefore, one of the objectives of the present invention is to provide a method of utilizing a ring oscillator to replace a phase-lock loop (PLL) to generate a clock, and sampling and identifying a signal according to the clock, and a related circuit thereof, to mitigate/avoid the above-described power consumption issues.

According to a first embodiment of the present invention, a method of signal identification is disclosed. The method includes: receiving a signal; utilizing a clock generated by a ring oscillator to sample the signal continuously to generate a plurality of sampled signals; counting each sampled signal length corresponding to successive sampled signals each having an identical value; and identifying a content of the signal according to a plurality of sampled signal lengths.

According to a second embodiment of the present invention, a signal identification apparatus is disclosed. The signal identification apparatus includes a receiving circuit, a ring oscillator, a sampling circuit, a counter, and a determining unit. The receiving circuit is arranged for receiving a signal. The ring oscillator is arranged for generating a clock. The sampling circuit is arranged for sampling the signal continuously to generate a plurality of sampled signals. The counter is arranged for counting each sampled signal length corresponding to successive sampled signals each having an identical value. The determining unit is arranged for identifying a content of the signal according to a plurality of sampled signal lengths.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a waveform of a COMRESET/COMINIT signal and a waveform of a COMWAKE signal according to the prior art.

FIG. 2 is a flowchart illustrating a method of signal identification according to an exemplary embodiment of the present invention.

FIG. 3 is a diagram illustrating a signal identification apparatus according to an exemplary embodiment of the present invention.

FIG. 4 is a flowchart illustrating the step of identifying the content of the signal according to the plurality of sampled signal lengths in the method of signal identification according to an exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

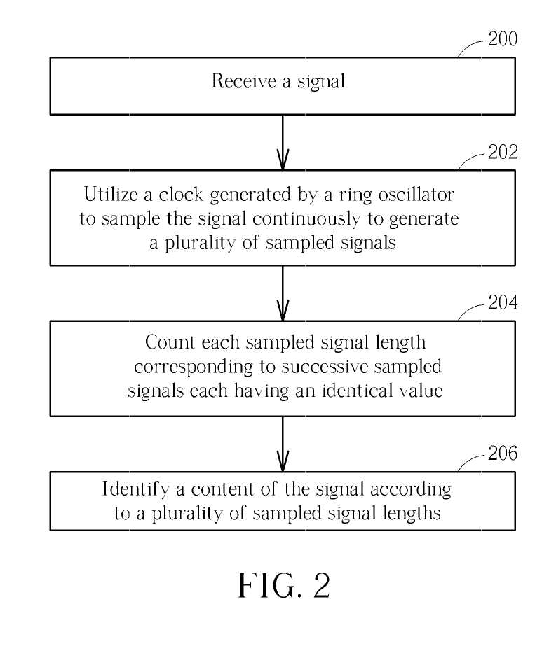

Please refer to FIG. 2, which is a flowchart illustrating a method of signal identification according to an exemplary embodiment of the present invention. Provided that substantially the same result is achieved, the steps of the flowchart shown in FIG. 2 need not be in the exact order shown and need not be contiguous, that is, other steps can be intermediate. Besides, some steps in FIG. 2 may be omitted according to various types of embodiments or requirements. The method may be briefly summarized as follows:

Step 200: Receive a signal;

Step 202: Utilize a clock generated by a ring oscillator to sample the signal continuously to generate a plurality of sampled signals;

Step 204: Count each sampled signal length corresponding to successive sampled signals each having an identical value; and

Step 206: Identify a content of the signal according to a plurality of sampled signal lengths.

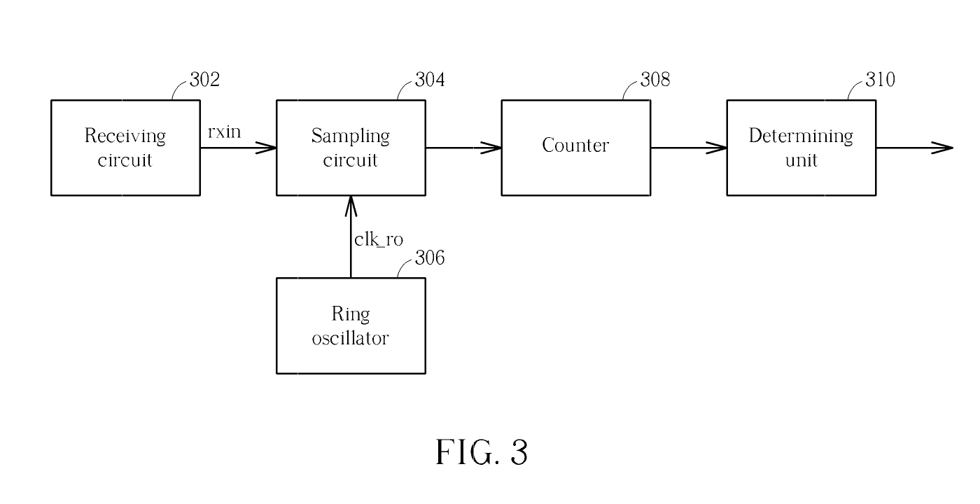

Regarding the method of signal identification as shown in FIG. 2, please also refer to FIG. 3. FIG. 3 is a diagram illustrating a signal identification apparatus according to an exemplary embodiment of the present invention. The signal identification apparatus 300 is used for performing the method of signal identification as shown in FIG. 2, and includes a receiving circuit 302, a sampling circuit 304, a ring oscillator 306, a counter 308, and a determining unit 310. It should be noted that the present embodiment is illustrated based on an application of a serial advanced technology attachment (SATA) device. In addition, the present embodiment is solely directed to the detection and identification of the OOB signals of a SATA device in the slumber mode. For example, a processing circuit for processing normal signals in the normal mode is not shown in FIG. 3. To put it another way, in the preferred embodiment of the present invention, the signal identification apparatus 300 is only used for detection and identification of the OOB signals received by the SATA device in the slumber mode, to replace the conventional design which utilizes the data path (including a phase-locked loop) used for receiving the normal signals in the normal mode to receive the OOB signals in the slumber mode. That is to say, the present invention can reduce power consumption of the SATA device in the slumber mode.

The receiving circuit 302 in the signal identification apparatus 300 is utilized to receive the incoming differential signals on the cable which complies with the SATA specification, and transmit a received signal rxin to the subsequent circuit (step 200). No matter whether the system is in the normal mode or the slumber mode, the receiving circuit 302 must maintain at an active state and convey the information on the transmission cable to the subsequent circuit in the same manner. When the system enters the slumber mode, the receiving circuit of the normal mode will be turned off, and the sampling circuit 304, the ring oscillator 306, the counter 308, and the determination unit 310 will be turned on. At this moment, since the phase-locked loop is also turned off to reduce power consumption, the ring oscillator 306 will be utilized to produce a clock CLK_RO for the sampling circuit 304 according to the present embodiment, thereby allowing the sampling circuit 304 to sample the signal rxin continuously in accordance with the clock CLK_RO to generate a plurality of sampled signals (step 202). It should be noted that, compared to a conventional phase-locked loop, the ring oscillator 306 has characteristics such as lower accuracy and lower power consumption. In addition, the frequency of the clock CLK_RO generated by the ring oscillator 306 needs to be set appropriately according to the frequency of the received signal rxin. In the SATA specification, the frequencies of the OOB signals are much lower than the frequency of the data signal; therefore, the frequency of the clock CLK_RO may be, for example, 300 MHz. However, this is not a limitation of the present invention. In practice, the clock frequency should be designed based on the signal frequency of the desired system signal to be identified. In addition, compared to the clock generated by the conventional phase-locked loop, the frequency of the clock CLK_RO produced by the ring oscillator 306 would be more inaccurate. For example, the error may reach 30%. Hence, there is a need for an appropriate identification mechanism/algorithm to reduce the identification error rate, and further details will be described in the following.

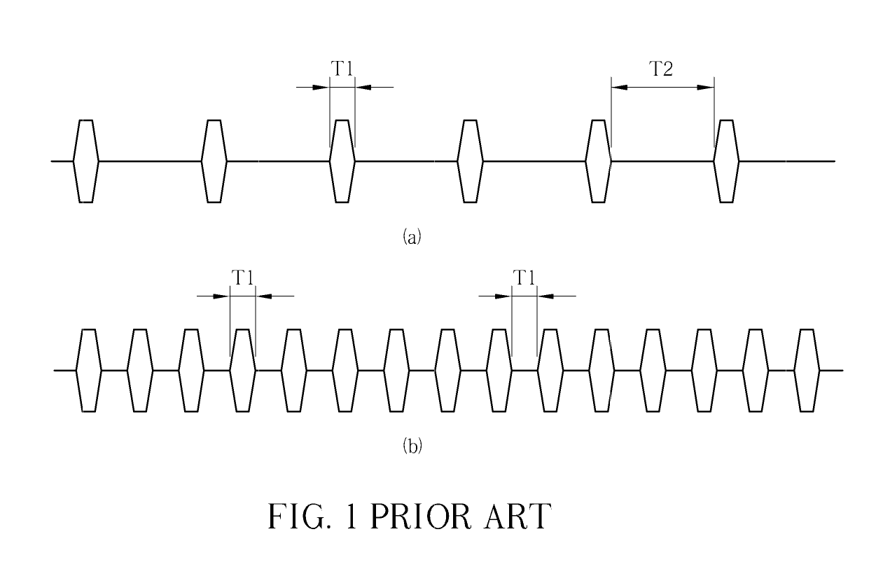

When the SATA device is remained in the slumber mode, the sampled signals outputted by the sampling circuit 304 will be ‘0’s, while when the SATA host tries to wake the SATA device up (i.e., when the host tries to control the device side to exit/leave the slumber mode and enter the normal mode), the host will send a first OOB signal COMREST/COMINIT shown in sub-diagram (a) of FIG. 1 or a second OOB signal COMWAKE shown in sub-diagram (b) of FIG. 1 to the device. At this time, the sampled signals of the sampling circuit 304 would have consecutive ‘1’s along with consecutive ‘0’s, wherein both the first OOB signal COMREST/COMINIT and the second OOB signal COMWAKE are composed of at least six bursts each having a first width T1 (106.7 ns), the spacing between the bursts of the first OOB signal COMREST/COMINIT is a second width T2 (320 ns), and the spacing between the bursts of the second OOB signal COMWAKE is the first width T1. Furthermore, with regard to the first OOB signal COMREST/COMINIT, the ratio of the burst signal (i.e., the width of the burst length) and an idle signal (i.e., the spacing between two adjacent bursts) is 1:3, and with regard to the second OOB signal COMWAKE, the ratio of the burst signal (i.e., the width of the burst length) and the idle signal (i.e., the spacing between two adjacent bursts) is 1:1.

In the step 204, the counter 308 is used to count each sampled signal length corresponding to successive sampled signals each having an identical value (e.g., consecutive ‘1’s or continuous ‘0’s) according to the clock CLK_RO generated by the ring oscillator 306, and then hand over to the subsequent determining unit 310 for identification. For example, in the slumber mode, the counter 308 will continue to accumulate the number of consecutive sampled signals ‘0’, and a specific value may be predetermined for resetting the counter 308 to filter out an excessive and meaningless count value when the number of consecutive sampled signals ‘0’ exceeds the specific value. When the host starts to send the first OOB signal COMREST/COMINIT or the second OOB signal COMWAKE, the counter 308 will count the number of consecutive sampled signals ‘1’, and when the signal has a transition from ‘1’ to ‘0’, the counter 308 will be reset and then start to accumulate the number of consecutive sampled signals ‘0’.

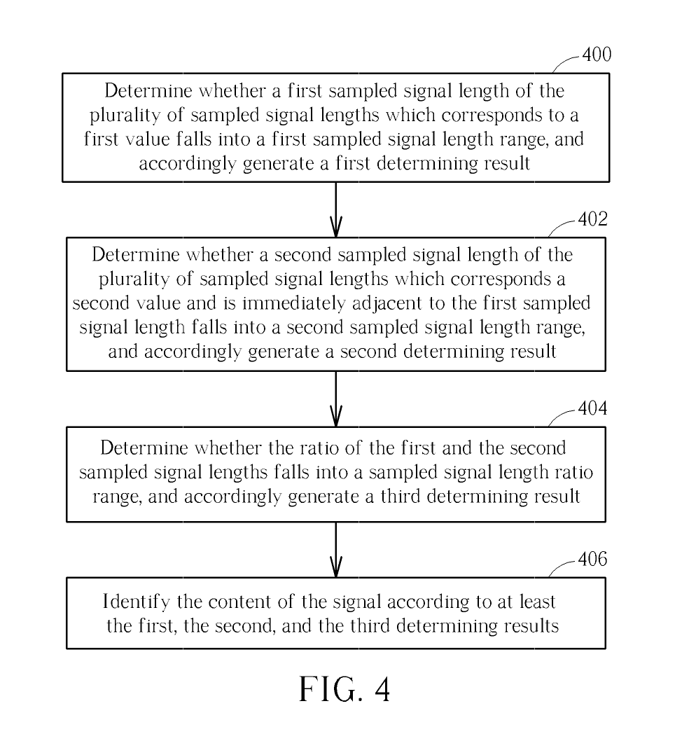

Regarding the operation of the determining unit 310, please refer to FIG. 4, which is a flowchart illustrating the step of identifying the content of the signal according to the plurality of sampled signal lengths in the method of signal identification according to an exemplary embodiment of the present invention. Provided that substantially the same result is achieved, the steps of the flowchart shown in FIG. 4 need not be in the exact order shown and need not be contiguous, that is, other steps can be intermediate. Besides, some steps in FIG. 4 may be omitted according to various types of embodiments or requirements. The method may be briefly summarized as follows:

Step 400: Determine whether a first sampled signal length of the plurality of sampled signal lengths which corresponds to a first value falls into a first sampled signal length range, and accordingly generate a first determining result;

Step 402: Determine whether a second sampled signal length of the plurality of sampled signal lengths which corresponds a second value and is immediately adjacent to the first sampled signal length falls into a second sampled signal length range, and accordingly generate a second determining result;

Step: 404: Determine whether the ratio of the first and the second sampled signal lengths falls into a sampled signal length ratio range, and accordingly generate a third determining result; and

Step 406: Identify the content of the signal according to at least the first, the second, and the third determining results.

First, each time the counter 308 receives the first OOB signal COMREST/COMINIT or the second OOB signal COMWAKE and transmits the counting result of signal ‘1’ corresponding to the burst (i.e., the first value) to the determination unit 310, the determining unit 310 would set the first sampled signal length range in step 400 according to the SATA specification as well as the maximum error of the ring oscillator 306. For instance, if the SATA specification defines that the length of each burst is between 103.5 ns and 109.9 ns, and the maximum error of the ring oscillator 306 is about 30%, the first sampled signal length range may be set by a range from (103.5 ns−103.5 ns×30%) to (109.9 ns+109.9 ns×30%), i.e. 72.45 ns-142.87 ns. However, this is for illustrative purposes only, and is not a limitation of the invention. In practice, the setting of the first sampled signal length range may be adjusted based on the specification of the application as well as the specification of the ring oscillator. If the counting result of signal ‘1’ (i.e., the first value) corresponding to the burst transmitted to the determining unit 310 by the counter 308 falls into the first sampled signal length range (in this embodiment, 72.45 ns-142.87 ns), then the determining unit 310 would generate the first determining result to indicate that the signal ‘1’ (i.e., the first value), which is representative of the burst, is received; otherwise, the first determining result indicates that no signal ‘1’ is received.

Next, the counter 308 will continue to transmit the counting result of the idle signal ‘0’ (i.e., the second value) between the bursts of the first OOB signal COMREST/COMINIT or the second OOB signal COMWAKE to the determining unit 310. At this moment, the determining unit 310 would set the second sampled signal length range in the step 402 according to the SATA specification as well as the maximum error of the ring oscillator 306. For instance, the spacing between adjacent bursts of the first OOB signal COMREST/COMINIT may be set by a value in a range from 35 ns to 175 ns, that is to say, the second sampled signal length range may be set to be delimited by 35 ns and 175 ns. However, this is for illustrative purposes only, and is not a limitation of the invention. In practice, the setting of the second sampled signal length range may be adjusted based on the specification of the application as well as the specification of the ring oscillator. As mentioned in the step 400, if the counting result of the idle signal ‘0’ (i.e., the second value) corresponding to the empty spacing between the bursts transmitted to the determining unit 310 by the counter 308 falls into the second sampled signal length range (in this embodiment, 35 ns-175 ns), then the determining unit 310 would generate the second determining result to indicate that the signal ‘0’ (i.e., the second value), which is representative of the empty spacing between the bursts, is received; otherwise, the second determining result indicates that no signal ‘0’ is received.

In addition, as described in the step 404, the disclosed embodiment of the present invention further determines whether the ratio of the first and the second sampled signal length falls within a sampled signal length ratio range, and accordingly generates a third determining result. In other words, in the steps 400 and 402, the SATA specification and the maximum error of the ring oscillator 306 are referred to for examining the absolute length of a single signal (i.e., either the burst signal or the idle signal), while in the step 404, the relative length ratio of two signals (i.e., the burst signal and the idle signal) is examined in accordance with the SATA specification and the maximum error of the ring oscillator 306. For example, based on the SATA specification, the ratio between the burst signal (i.e., the length of the burst signal) and the idle signal (i.e., the spacing between two consecutive bursts) of the first OOB signal COMREST/COMINIT should be 1:3, while the ratio between the burst signal (i.e., the length of the burst signal) and the idle signal (i.e., the spacing between two consecutive bursts) of the first OOB signal COMWAKE should be 1:1. Therefore, the sampled signal length ration range of the burst signal and the idle signal of the first OOB signal COMREST/COMINIT (i.e.,

$$\frac{idle signal}{burst signal} )$$

may be set by a range from 2 to 4, if the clock error of the ring oscillator is considered. For another example, the sampled signal length ration range of the burst signal and the idle signal of the second OOB signal COMWAKE (i.e.,

$$\frac{idle signal}{burst signal} )$$

may be set by a range from 0.5 to 1.5. However, this is for illustrative purposes only, and is not a limitation of the invention. In practice, the setting of the sampled signal length ration range of the burst signal and the idle signal can be adjusted based on the specification of the application as well as the specification of the ring oscillator.

In general, different application may have different specifications of signal identification. For example, in the SATA specification, 6 consecutive burst signals separated by 6 idle signals (i.e., 6 consecutive groups each having a burst signal and an idle signal) are required for confirmation of receiving the first OOB signal COMREST/COMINIT or the second OOB signal COMWAKE in order to avoid any misjudgment caused by noise. Therefore, the steps 400 to 404 may be repeatedly performed for each group of the burst signal and the idle signal to obtain the corresponding first, second, and third determination results; and finally, the step 406 refers to each set of the first, second, and third determining results to confirm whether a group of the burst signal and the idle signal which complies with the signal characteristics of the first OOB signal COMREST/COMINIT or the second OOB signal COMWAKE is received. In other words, the step 406 may continuously validate N sets of the first, second, third determination results (for example, N=6), and does not confirm that the first OOB signal COMREST/COMINIT or the second OOB signal COMWAKE is confirmed until all the conditions are recognized and satisfied. After the OOB signal reception is confirmed, the SATA device is controlled to exit the slumber mode. That is, the SATA device restarts all the circuit blocks which were turned off in the slumber mode.

In addition, the above description illustrates the preferred embodiment of the present invention; however, the present invention is not limited to such an embodiment. In fact, any design which performs the OOB signal identification based on a clock provided by a ring oscillator obeys the spirit of the present invention. For example, in another embodiment, the step 404 shown in FIG. 4 may be omitted, and the step 406 may be modified as identifying the content of the signal based on at least the first and the second determining results. In yet another embodiment, the step 404 shown in FIG. 4 may be omitted, and the step 406 may be modified as identifying the content of the signal based on at least the first and the second determining results; besides, the steps 400 and 402 will be repeatedly executed for each group of the burst signal and the idle signal to obtain the corresponding first and second determination result; and finally, in the step 406, it can be determined whether a group of the burst signal and the idle signals that complies with signal characteristics of the first OOB signal COMREST/COMINIT or the second OOB signal COMWAKE is received by referring to the first and second determining results of each group.

Compared with the conventional designs which has to keep the phase-locked loop active in a power saving mode to keep waiting for the wake-up command of a specific signal, the signal identification method and apparatus of the present invention which uses a ring oscillator to replace a phase-locked loop can greatly reduce the power consumption in the power saving mode (or the slumber mode). In this way, the standby time of a mobile device or a laptop computer can be extended, thus achieving the objective of energy saving.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of signal identification, comprising:
receiving a signal;
utilizing a clock generated by a ring oscillator to sample the signal continuously to generate a plurality of sampled signals;
counting each sampled signal length corresponding to successive sampled signals each having an identical value; and
identifying a content of the signal according to a plurality of sampled signal lengths.

2. The method of signal identification of claim 1, wherein the signal is an Out-of-Band (OOB) signal utilized in a Serial Advanced Technology Attachment (SATA).

3. The method of signal identification of claim 1, wherein the step of identifying the content of the signal according to the plurality of sampled signal lengths comprises:
determining whether a first sampled signal length of the plurality of sampled signal lengths which corresponds to a first value falls into a first sampled signal length range, and accordingly generating a first determining result;
determining whether a second sampled signal length of the plurality of sampled signal lengths which corresponds to a second value and is immediately adjacent to the first sampled signal length falls into a second sampled signal length range, and accordingly generating a second determining result; and
identifying the content of the signal according to at least the first and the second determining results.

4. The method of signal identification of claim 3, wherein the step of identifying the content of the signal according to the plurality of sampled signal lengths further comprises:
determining whether a ratio of the first and the second sampled signal lengths falls into a sampled signal length ratio range, and accordingly generating a third determining result; and
the step of identifying the content of the signal according to at least the first and the second determining results comprises:
identifying the content of the signal according to at least the first, the second, and the third determining results.

5. The method of signal identification of claim 3, wherein the step of identifying the content of the signal according to the plurality of sampled signal lengths further comprises:
determining whether a third sampled signal length of the plurality of sampled signal lengths which corresponds to the first value and is immediately adjacent to the second sampled signal length falls into the first sampled signal length range, and accordingly generating a third determining result; and
determining whether a fourth sampled signal length of the plurality of sampled signal lengths which corresponds to the second value and is immediately adjacent to the third sampled signal length falls into the second sampled signal length range, and accordingly generating a fourth determining result; and
the step of identifying the content of the signal according to at least the first and the second determining results comprises:
identifying the content of the signal according to at least the first, the second, the third, and the fourth determining results.

6. The method of signal identification of claim 5, wherein the step of identifying the content of the signal according to the plurality of sampled signal lengths further comprises:
determining whether a ratio of the first and the second sampled signal lengths falls into a sampled signal length ratio range, and accordingly generating a fifth determining result; and
determining whether a ratio of the third and the fourth sampled signal lengths falls into the sampled signal length ratio range, and accordingly generating a sixth determining result; and
the step of identifying the content of the signal according to at least the first, the second, the third, and the fourth determining results comprises:
identifying the content of the signal according to at least the first, the second, the third, the fourth, the fifth, and the sixth determining results.

7. A signal identification apparatus, comprising:
a receiving circuit, arranged for receiving a signal;
a ring oscillator, arranged for generating a clock;
a sampling circuit, arranged for sampling the signal continuously to generate a plurality of sampled signals;
a counter, arranged for counting each sampled signal length corresponding to successive sampled signals each having an identical value; and
a determining unit, arranged for identifying a content of the signal according to a plurality of sampled signal lengths.

8. The signal identification apparatus of claim 7, wherein the signal is an Out-of-Band (OOB) signal utilized in a Serial Advanced Technology Attachment (SATA).

9. The signal identification apparatus of claim 7, wherein the determining unit determines whether a first sampled signal length of the plurality of sampled signal lengths which corresponds to a first value falls into a first sampled signal length range, and accordingly generates a first determining result; determines whether a second sampled signal length of the plurality of sampled signal lengths which corresponds a second value and is immediately adjacent to the first sampled signal length falls into a second sampled signal length range, and accordingly generates a second determining result; and identifies the content of the signal according to at least the first and the second determining results.

10. The signal identification apparatus of claim 9, wherein the determining unit further determines whether a ratio of the first and the second sampled signal lengths falls into a sampled signal length ratio range, and accordingly generates a third determining result; and identifies the content of the signal according to at least the first, the second, and the third determining results.

11. The signal identification apparatus of claim 9, wherein the determining unit further determines whether a third sampled signal length of the plurality of sampled signal lengths which corresponds to the first value and is immediately adjacent to the second sampled signal length falls into the first sampled signal length range, and accordingly generates a third determining result; and determines whether a fourth sampled signal length of the plurality of sampled signal lengths which corresponds to the second value and is immediately adjacent to the third sampled signal length falls into the second sampled signal length range, and accordingly generates a fourth determining result; and the determining unit identifies the content of the signal according to at least the first, the second, the third, and the fourth determining results.

12. The signal identification apparatus of claim 11, wherein the determining unit further determines whether a ratio of the first and the second sampled signal lengths falls into a sampled signal length ratio range, and accordingly generates a fifth determining result; and determines whether a ratio of the third and the fourth sampled signal lengths falls into the sampled signal length ratio range, and accordingly generates a sixth determining result; and the determining unit identifies the content of the signal according to at least the first, the second, the third, the fourth, the fifth, and the sixth determining results.
